(19) United States
(12) Patent Application Publication
(10) Pub. No.: US 2005/0028361 A1
(43) Pub. Date: Feb. 10, 2005

(54) Integrated underfill process for bumped chip assembly

(75) Inventors: Wushing Yin, Clinton, NY (US); Ning-Cheng Lee, New Hartford, NY (US)

Correspondence Address: WEINGARTEN, SCHURGIN, GAGNEBIN & LEBOVICI LLP, TEN POST OFFICE SQUARE, BOSTON, MA, 02109, US

(73) Assignee: Indium Corporation of America

(21) Appl. No.: 10/636,105

(22) Filed: Aug. 7, 2003

(51) Int. Cl. H05K 3/30

(52) U.S. Cl. 29/841; 29/832; 29/840

(57) ABSTRACT

An integrated underfilling process for attaching a chip/die having conductive solder bump contacts to a substrate. The process involves B-staging filled underfill on the chip/die, depositing a fluxing unfilled underfill onto the surface of the substrate, mating the chip/die with the B-staged underfill to the substrate and reflowing the assembled chip/substrate. The B-staged filled underfill reduces the coefficient of thermal expansion of the underfill fillet and the fluxing unfilled underfill removes metal oxide from the surface of the solder bump contacts and bond pads to promote the formation of reliable metallurgical joints.

### CROSS REFERENCE TO RELATED APPLICATIONS

Not Applicable

### STATEMENT REGARDING FEDERALLY SPONSORED RESEARCH OR DEVELOPMENT

Not Applicable

### BACKGROUND OF THE INVENTION

The present invention relates to assembly of integrated circuit (“IC”) packages, such as flip chip, chip scale and ball grid array (BGA) packages using underfill.

Flip chip, chip scale package (CSP) and ball grid array (BGA) are various forms of integrated circuit packages. Such packages are designed to meet the demands of the ever-increasing requirements for higher I/O density, miniaturization, and improved electrical performance.

A chip or die is typically mounted on an substrate with interconnect material to form an IC assembly. Due to the large mismatch between the coefficient of thermal expansion (CTE) of silicon chips, laminate boards (i.e., substrate) and solder interconnects, electrical failures associated with the interconnect between the IC and the substrate are relatively common. In order to improve the reliability of the semiconductor devices, underfill encapsulants that are introduced between the IC and the substrate have been developed. Underfill encapsulants provide mechical support for the IC/substrate interconnect and are intended to reduce the likelihood of a failure of the connnections between the IC and the substrate.

Underfills typically involve the mixture of an epoxy resin and a filler which are disposed in the gaps between the chip or die and the substrate to reduce the thermomechanical stress on the chip connection caused by the mismatch in CTE among the chip, the substrate and the solder joints and to achieve higher reliability solder joints.

In the traditional capillary underfill process, the chip or die is aligned with the pads on the substrate and reflowed to form electrical connections and mechanical joints between IC and the substrate. After soldering, a solvent cleaning step is usually introduced to remove the flux residue which would tend to adversely affect the underfill adhesion and degrade solder joint reliability. The cleaning process is a difficult operation that is typically costly and time consuming. Moreover, the cleaning process typically requires the use of solvents and expensive processing equipment. After soldering of the chip or die bumps (contacts) to the substrate to remove flux residue, the underfill is dispensed onto the substrate along the edge of the chip or die, followed by underfill cure. The success of this method is limited, however, by the die size and gap size between the chip and the substrate. This method also reduces the throughput during the manufacturing process. Therefore, there is a need to develop a new technology, which can enhance throughput and can be applied to the smallest gap such as 1-2 mils for large chip or dies.

A no-flow underfill process was developed to address the problem posed by the small clearance between the chip or die and the substrate. This process improves the manufacturing throughput by eliminating the cleaning process and combines the solder reflow process and underfill cure in one step. More specifically, in the no-flow underfill process, underfill is deposited onto the surface of a substrate. The bumps of chip or die are aligned with the corresponding pads on the substrate. The bumps of the chip or die are then pushed through the underfill material until the bumps are in contact with the corresponding pads on the substrate.

FIG. 1 shows a schematic view of a die and package for mounting a chip to a substrate using the no-flow underfill process. Referring to FIG. 1, the substrate 110 contains a plurality of metallurgical pads 112 on the substrate surface. The flip chip or die 115 includes a plurality of solder bumps 116 on a surface arranged in a pattern to mate with corresponding pads on the substrate. The flip chip or die 115 is mated with the substrate containing no-flow underfill 114. The bumps 116 of flip chip or die 115 are urged into contact with the conductive pads 112 on the substrate 110 by applying pressure to the flip chip or die 115 such that the bumps are pushed through the no-flow underfill 114 and abut the respective pads 112. The bumps 116 of the chip or die 115 are joined with the pads 112 on the substrate 110 via solder joints 118 through a solder reflow process.

The above-described no-flow underfill process results in high open defects whereby the bumps 116 fail to make contact with the pads 112 due to filler particles that are trapped between the respective flip chip bump 116 and the respective substrate pads 112. This problem is not resolved by reducing or eliminating filler in the no-flow underfill since the reduction or elimination of filler results in a CTE mismatch.

In order to overcome the problems associated with the above-described no-flow underfill process, a two-layer no-flow underfill system has been developed. This system is described in Zhang et al., “A Novel Approach for Incorporating Silica Fillers into No-Flow Underfill”, Proceedings of the 51st Electronic Components and Technologies Conference, pp. 310-316, (2001). In this system a coating with no filler is applied to the substrate and subsequently a coating that contains filler is applied. Next, the component is placed on the substrate. This process however is costly in a production environment because it involves multiple depositions.

In order to introduce filler into no-flow underfill, a wafer-level underfill process has been developed. FIG. 2 is a schematic view showing a wafer 200 having a plurality of chips 210 formed thereon, with each of the chips 210 having a plurality of bumps or contacts 212. In the wafer-level underfill process, filled underfill is applied to the wafer passivation layer 218. After applying the filled underfill to the passivation layer, the underfill is subjected to soft-baking or B-staging. Following this curing step, the tips of the bumps are coated with the underfill. Chemical or mechanical methods, or combinations thereof, are employed to remove the underfill from the top of the bumps 212 and expose the tip of the bumps 212. Such methods include polishing or grinding, dry/wet etching, chemical mechanical polish (CMP), reactive ion etching (RIE), laser milling, and laser ablation. After underfill removal, the wafer 200 is diced to separate the chips 210.

Another wafer-level underfull process for individual chip assembly is depicted in FIG. 3. In this process the filled underfill 312 is applied to the wafer over the bumps 300 of a flip chip or die 310. The underfill 312 is then subjected to soft baking or B-staging. The flip chip or die 310 with B-staged underfill 312 is mated to the substrate 316 with the bumps 300 of the chip or die 310 abutting the pads 315 of the substrate 316, as shown in FIG. 3c. After the chip or die 310 with B-staged underfill 312 is placed on the substrate, the bumps 300 are conductively coupled to the pads 315 to form solder joints via a reflow process. The assembly is reinforced by the cured underfill fillet 319, as shown in FIG. 3. In the process depicted in FIG. 3, the amount of underfill deposited is very important for success. In particular, if too little underfill is applied a number of solder joints are likely to experience insufficient wetting. Additionally, if too much underfill is applied, the die is likely to float or be skewed in alignment.

In order to enhance solder wetting, a multi-layer wafer-level applied underfill process has been developed which is described in U.S. Published Patent Application No. US2003/0109080 A1. This process differs from the two-layer no-flow underfill process described previously. The process involves applying several layers of filled underfill onto the wafer passiviation layer which are subject to successive soft baking steps. Each layer typically ranges in thickness from 15 μm to 20 μm. After the soft baking steps, the underfill on the bumps is removed to expose the tip of the bumps. A final layer of unfilled underfill is then applied to the surface of filled underfill.

This multi-layer wafer-level applied underfill process enhances solder wetting when compared with the earlier attempt on wafer-level applied underfill, which uses filled underfill only. However, when applied onto the passivation layer of the wafer, the underfill layer may not form a parallel planar region surrounding the bumps, but may instead show a contoured curvature rising towards the bump surface. On the other hand, because the substrate is generally a non-coplanar surface, the B-staged underfill in the chip or die cannot wet the non-coplanar surface of the substrate. The contoured curvature of the B-staged underfill and the non-coplanar surface of the substrate will be major contributors to underfill voids surrounding solder joints because the entrapped air bubble between the die and the substrate can not easily escape in highly viscous B-staged underfill during reflow. Accordingly, poor reliability for the packaged device can result.

A conflicting requirement between fillet formation and die skewing is another problem. A thick underfill coating is needed for good fillet formation. However, excessive underfill material inevitably results in die skewing. Reducing the coating thickness may alleviate the die skewing problem, however, poor solder contact wetting occurs and fillet formation is not always satisfactory.

With the advancement of integrated technology, the number of I/O contacts is increasing and bump and pitch sizes are decreasing. Consequently, current underfill processes are likely to have difficulties with small devices, especially in the case of high density contacts. Therefore it would be desireable to have an underfill process for assembly of bumped chips or dies that may be used in the assembly of devices having high density contact patterns and that avoids the problems associated with the above-described processes.

### SUMMARY OF THE INVENTION

In accordance with the present invention a method for assembling a chip or integrated circuit (IC) die to a substrate using a single step integrated underfilling process is disclosed. The integrated underfilling process comprises the steps of (1) coating a thick layer, which may contain one or more layers of filled underfill, onto the passivation layer of the bumped chip or die, which could be an individual die or a plurality of dies in a wafer; (2) depositing a thin layer of unfilled no-flow underfill or polymer flux onto the substrate; (3) placing the bumped chip or die with B-staged underfill onto the substrate with pre-deposited no-flow underfill; and (4) reflowing the assembled chip or die in an oven.

A thin layer of unfilled fluxing/no-flow underfill or polymer flux or a lightly filled underfill is applied to the substrate, and a thick layer of filled underfill is applied onto the passivation layer of the bumped chip or die. The thin layer of unfilled fluxing/no-flow underfill or lightly filled underfill allows easy wicking onto the chip or die, thus preventing the entrapment of air bubbles during the chip or die placement process and reducing the likelihood of die skewing or floating. The low viscosity allows easy wetting on the non-coplanar substrate surface and also facilitates solder wetting. The self-centering force resulting from the molten solder joint further reduces the likelihood of die skewing. A thick layer of filled underfill, which could form a low CTE interface, provides high reliability for the IC package.

In one embodiment, the integrated method of underfilling a device on a substrate during a reflow process combines the soldering and underfilling processes and the underfill curing in one step. The incorporation of underfilling into the solder reflow process removes the typical bottleneck of the manufacturing process, thus significantly shortening the manufacturing cycle.

Additionally filler is incorporated into the fluxing underfill/no-flow underfill system. The filled underfill is deposited on the flip chip or IC die, which will not interfere with solder reflow. During the reflow process, the filled underfill is transformed from a solid to a liquid with increasing temperature, and filler settles into the unfilled underfill layer to form a homogenous underfill layer for the assembled device. As a consequence, the problem of poor reliability of the resultant devices due to a CTE mismatch between the unfilled no-flow underfill and the die or substrate is avoided.

The integrated underfilling process provides a high yield process and void free underfill for the final product. Because a thin layer of unfilled underfill is allowed to flood and flow into the gap between chip and substrate, the underfill material is able to wet any contacted surface and replaces the air space underneath the die with underfill material, avoiding the formation of air bubbles, and assuring that void free underfill is formed during the reflow process. Unlike the wafer-level applied underfill process, a thin layer of unfilled underfill, illustrated in this embodiment, is able to flow at room temperature. Upon placement of die, the unfilled underfill is squeezed aside easily and forms a nice fillet. The filled underfill stabilizes the chip or die during reflow by increasing the weight of the chip or die, and thus further minimizes die skewing. The process is more easily controllable due to the good wetting capability and flowability of the unfilled underfill thin layer.

Other features, aspects and advantages of the above described process for mounting a bumped chip or die to a substrate will be apparent to those of ordinary skill in the art from the Detailed Description of the Invention that follows.

### BRIEF DESCRIPTION OF THE DRAWINGS

The invention will be more fully understood by reference to the following Detailed Description of the Invention in conjunction with the drawing of which:

FIGS. 1a-1d depict a prior art technique for mounting a die to a substrate in accordance with a conventional no-flow underfill process;

FIG. 2 is a schematic view showing a prior art wafer having a plurality of chips formed thereon, wherein each of the chips includes a plurality of conductive bumps or contacts;

FIG. 3a-d is a schematic view of a prior art wafer-level applied underfill process for individual chip assembly;

FIG. 4a is a schematic cross-sectional view of a flip chip or IC die with a plurality of conductive bumps contacts disposed on conductive pads;

FIG. 4b is a schematic cross-sectional view showing the chip or IC die of FIG. 4a having a filled underfill coating;

FIG. 4c is a schematic cross-sectional view of the chip or IC of FIG. 4b and a substrate with conductive pads coated with an unfilled underfill prior to mating of the chip or IC die with the substrate;

FIG. 4d is a schematic cross-sectional view of the chip or IC die of FIG. 4b disposed in contact with the substrate of FIG. 4c prior to reflow; and

FIG. 4e is a schematic cross-sectional view of a chip or IC die and substrate depicted conductive contacts of the chip or IC die mated with corresponding metallurgical pads of the substrate subsequent to reflow.

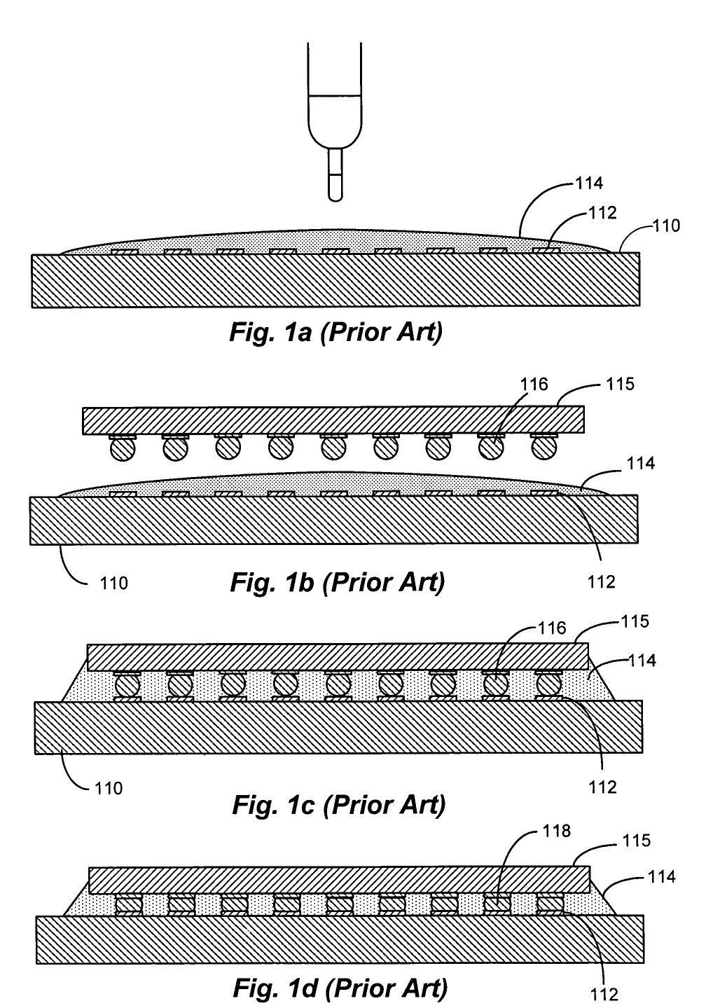

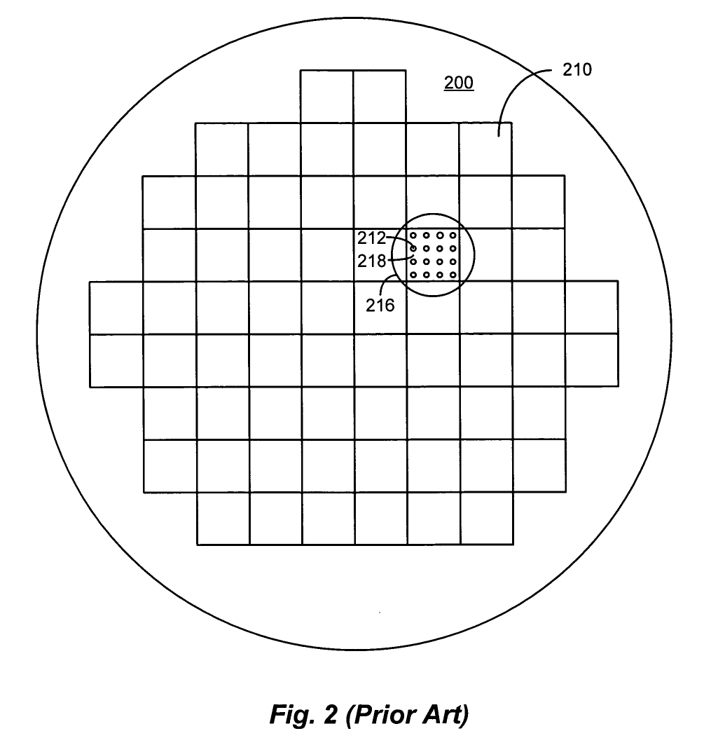

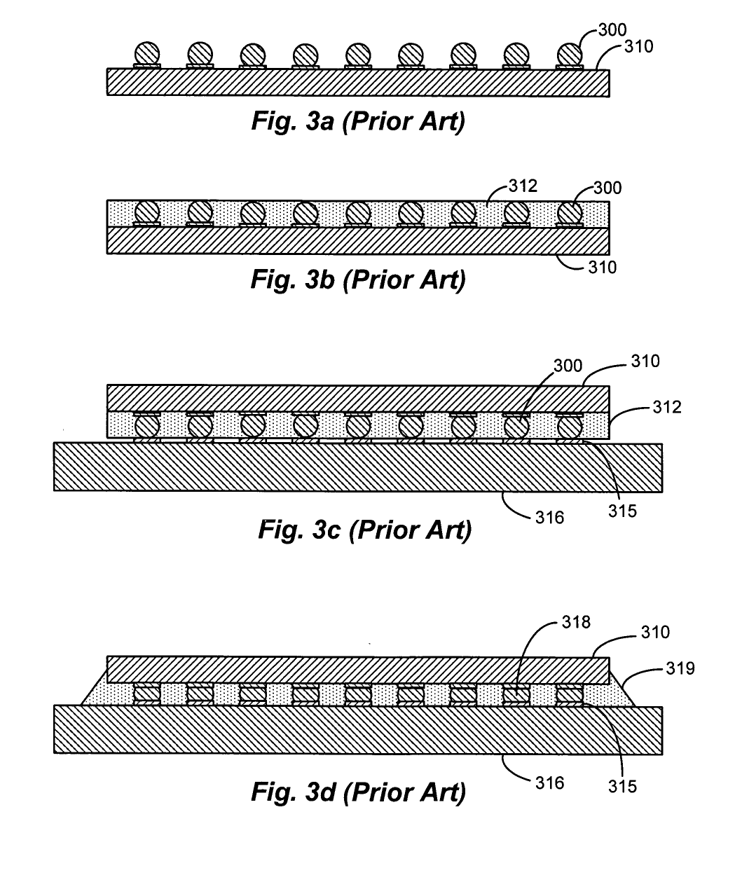

### DETAILED DESCRIPTION OF PREFERRED EMBODIMENT

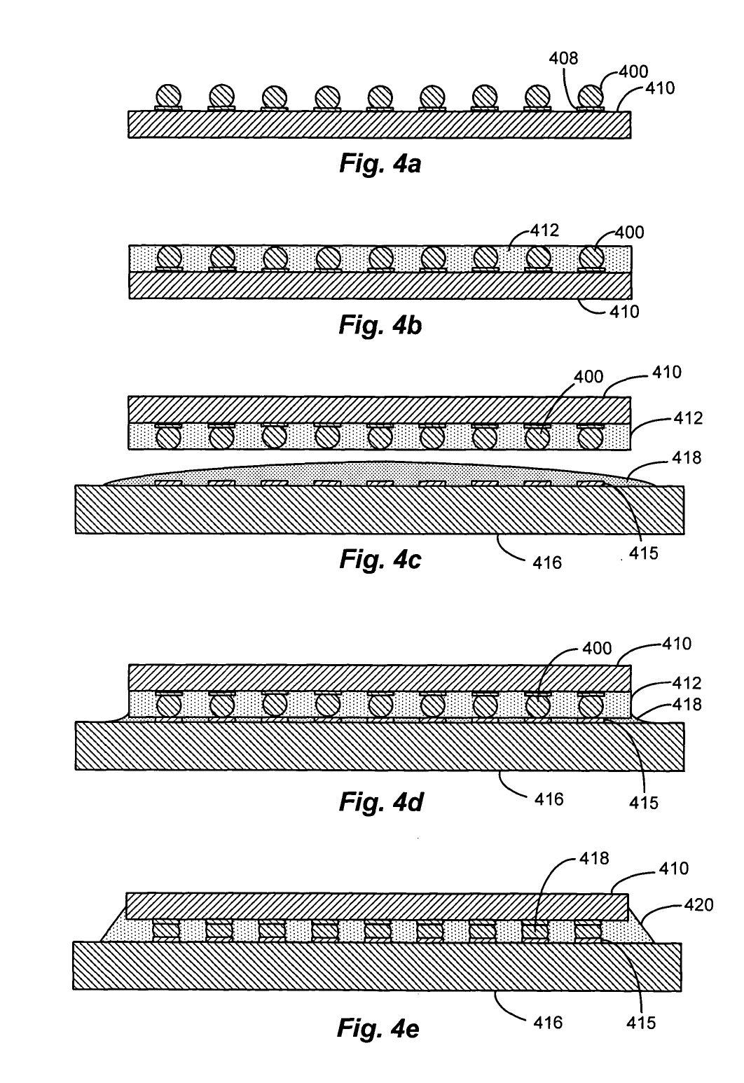

In accordance with the present invention a method and system for assembling a chip or IC die to a substrate is disclosed. FIG. 4a shows a schematic view of a chip or die 410 with a plurality of conductive bumps 400. The conductive bumps 400 are typically disposed on metallurgical pads 408 disposed on a surface of the chip or die 410. The die 410 may be one of a plurality of dies in wafer. The presently disclosed process may be applied to individual dies, e.g. die-level processes, and to a collection of dies in a wafer, e.g. wafer-level processes. Generally a die 410 has a surface containing metallurgical pads 408 and corresponding chip bumps or contacts 400. The bumps may be of any suitable conductive materials, e.g. eutectic SnPb solders, high Pb solders, lead free solders, Sn and Sn alloy solders, and metals such as Cu, Au, Ag, Ni, Sn, or suitable alloys thereof. Preferably, the chip or IC die bump materials will have a melting point above 100° C. Prior to applying underfill materials, the die surface is preferably covered with an initial passivation layer and/or a protection compliant layer, e.g. polyimide.

FIG. 4b is a schematic view depicting an underfilled chip or die. More specifically, at least one coating of underfill 412 is applied to chip or die 410. Various processes may be used to apply underfill 412 to the wafer or individual chip or die. Examples of such processes include spin-on, dispense, coating (e.g. by brushing or spraying a liquid), lamination (e.g. by applying a solid film or sheet), and screen-printing.

After the underfill 412 is applied to the chip or die 410, the underfill 412 is typically B-staged or soft baked to partially cure the underfill 412. However, the B-staged underfill 412 may vary from zero cured to fully cured underfill. Soft baking refers to the process of partially curing the underfill 412 or evaporating solvents from the underfill 412 to form a solid state material at room temperature. The B-staged condition can be optimized depending on the particular underfill materials. Preferably, the B-staged underfill can be liquidified and further fully cured during reflow process. It should be noted that partial curing of the underfill may be performed by B-staging, soft baking, the application of compressed gas, hot gas drying, oven heating, UV light curing, IR baking or any other suitable process.

The underfill 412 may be removed from the tips of the bumps 400 to expose the conductive tips via any suitable process. The underfill removal step preferably occurs only once after all underfill layers have been applied. Alternatively, underfill may be removed after applying individual underfill layers as needed. Methods for removing the underfill 412 from the tips of the bumps 400 include polishing or grinding, dry/wet etching, chemical mechanical polish (CMP), reactive ion etching (RIE), laser milling, and laser ablation.

Underfill 412 is typically a mixture of polymeric materials with an inorganic filler. Examples of underfill materials include epoxy system (e.g. bisphenol A epoxy resins, bisphenol F epoxy resins, cycloaliphatic epoxy resins, naphthalene epoxy resin and/or mixtures thereof), cyanate esters system, siloxiranes system, maleimides system, polybenzoxazines system, and polyimides system. One layer may be applied to the passivation layer of the flip chip or die 410 or alternatively, a number of layers of underfill with different properties may be applied to the passivation layer of the flip chip or die 410. For example, the different properties may be selected to obtain different desired properties such as good adhesion to the passivation layer, a desired coefficient of thermal expansion, a desired Young's modulus, and/or fracture resistance. When a plurality of underfill layers are applied, the previous layer is typically B-staged or soft baked prior to the application of next underfill layer. The underfill 412 may optionally have some flux capability. The number and thickness of the underfill layers is not limited and can vary based on the specific application, which are dependent on its nature (reflowable or non-reflowable) and the bump height of the chip or die. The number of underfill layers is typically between 1 to 20 layers. More typically, 2 to 3 layers are adequate. The thickness of each layer of underfill 412 can be varied for specific applications as needed. Preferably, the underfill layers range in thickness from 4 μm to 40 μm, more preferably from 12.5 μm to 25 μm.

Hardeners (crosslinking agents) in the underfill 412 may be anhydride, phenolic resin or amine. Anhydride can be selected from the group consisting of hexahydrophthalic anhydride, methyl hexahydrophthalic anhydride, methyl-5-norborene-2,3-dicarboxylic anhydride, tetrahydrophthalic anhydride, methyl tetrahydrophthalic anhydride, nadic methyl anhydride, other anhydrides and mixtures thereof. Phenolic resins may be bisphenol A, bisphenol F, other phenols, and mixtures thereof. Amines may be Diethylene triamine, triethylene tetramine and other amines, or mixtures thereof.

Filled underfill is underfill that contains fillers. The use of filled underfill allows for optimizing the coefficient of thermal expansion as needed which can result in improved reliability of the assembled device following mating of the chip or die 410 to a substrate. The filler may be a powered inorganic material, e.g. silica, quartz, alumina, boron nitride, carbon, or aluminum nitride or mixture thereof. Alternatively, the filler may be micro-fiber that can be selected from micro polymer fibers or inorganic micro fibers, e.g. micro-glass fiber. The amount of fillers employed is specified based upon the application requirements, however it may vary widely. Preferably, the coefficient of thermal expansion of the underfill can be controlled within the range of 3 ppm/° C. to 30 ppm/° C. by the addition of a filler.

FIG. 4c shows a schematic view of the underfilled chip or die that has been placed in opposed relation with the substrate 416 prior to the mating of the chip or die to the substrate 416. In one embodiment, at least one layer of unfilled or lightly filled underfill 418 is applied on the substrate prior to the placement of B-staged underfilled chip or die. The substrate 416 typically contains coplanar metallurgical bond pads 415, and may contain substrate bumps (not shown), which are suitable for mechanical and electrical mating with the corresponding chip bumps 400. The bumps are preferably solder bumps, but other conductive materials may be used instead of solder. The substrate 416 is generally made of silicon, ceramic, glass, FR-4, BCB, polyimide, a combination thereof or another suitable material.

Preferably, the filler load in the unfilled or lightly filled underfill 418 ranges in weight from 0 to 30%, although typically the filler load will range between 0 and 10% by wieight. The underfill 418 may contain a fluxing agent. During reflow, the fluxing agent removes the oxide on the surface of solder bumps 400 mounted to the chip 410 and the oxide on the bond pads 415 on the substrate 416, and allows mechanical and electrical solder joints to form between the chip/die 410 and the substrate 416. Generally, the fluxing agent may be acidic, basic, neutral chemicals, or a combination thereof. Acidic chemicals may be organic acid, e.g. suberic acid, succinic acid, acrylic acid, lauric acid, plamitic acid, valeric acid, etc. The fluxing agent may be organic base, e.g. imidazole, imidazole derivatives, methylene dianiline, etc. The fluxing agent may also be a neutral organic hydoxyl group containing chemicals, e.g. alcohol or polyol.

FIG. 4d depicts the underfilled chip or die 410 after alignment and placement of the chip or die 410 onto the underfilled substrate 416. During placement, the unfilled underfill 418 may wet all space and eliminate air bubbles between the chip/die 410 and the substrate 416 to reduce the likelihood of voids. Because the underfill 418 that is applied to the substrate 416 is a liquid with a very low viscosity, the excess underfill 418 can be squeezed out of the gap between the chip/die 410 and the substrate 416 during chip/die 410 placement, thus eliminating chip/die skewing or floating during reflow. The liquid underfill 418 provides a better flux capability and flowability than the B-staged unfilled underfill described above.

Various processes can be utilized to apply the underfill 418 to the substrate 416. For example, the underfill 418 may be applied to the substrate via a spin-on application process, by dispensing the underfill 418 on the substrate 416, via a coating or printing process or via any other suitable method for the transfer of the underfill 418 onto the substrate 416.

FIG. 4e depicts the die 410 assembled onto substrate 416 after reflow with the metallurgical pads of the chip/die 410 conductively mated to the corresponidng pads 415 on the substrate 416. During reflow, the B-staged underfill 412 on the chip/die 410 is liquidified and the filler in the filled underfill 412 mixes with the underfill 418 to form a generally homogeneous underfill that is disposed betweent the die 410 and the substrate 416. The amount of filled underfill is preferably nearly sufficient to fill the gap between the chip/die 410 and the substrate 416 in order to avoid buoyancy force. The fluxing agent in underfill 418 removes metal oxide from the chip/die bumps 410 and pads to allow reliable solder joints to be formed between the chip/die 410 and the substrate 416. The mixed underfill may be cured during the reflow process or alternatively, a further curing process may be performed to promote the curing of the mixed underfill 420. Reflow may be performed via an infra red (IR) reflow process, via forced hot gas convection, oven heating or any other suitable reflow process known in the art.

While embodiments of the invention have been described above, those embodiments illustrated do not intend to restrict or in any way limit the scope of the present invention. It is common to those skilled in the art to have additional modifications, variations, substitutions and equivalents in practicing the invention without departing from the spirit of the current invention as defined by the appended claims.

1. A method for mating an integrated circuit device having a plurality of conductive contacts with contact tips arranged in a predetermined pattern and extending from one surface of said device to a substrate having a plurality of conductive pads arranged on one surface of said substrate in said predetermined pattern, said method comprising the steps of:
applying a layer of a first underfill to said surface of said device having said contacts extending therefrom;
partially curing said first underfill;
applying a layer of a second underfill to at least said conductive pads of said substrate surface;
aligning said device with said substrate such that said contacts are adjacent corresponding pads; and
subjecting said device and said substrate to a reflow process to conductively couple said conductive contacts to said conductive pads.

2. The method of claim 1 wherein said first underfill applying step comprises the step of applying a filled underfill to said surface of said device having said contacts extending therefrom.

3. The method of claim 1 wherein said first underfill applying step comprises the step applying at least one layer of said first underfill to said surface of said device having said contacts extending therefrom; and partially curing each of said at least one layer.

4. The method of claim 3 further including the step of applying at least one layer of said first underfill to said surface of said device having said contacts extending therefrom and partially curing each of said at least one layer, wherein at least one of said at least one layer of said first underfill is selected to reduce the coefficient of thermal expansion of the first underfill.

5. The method of claim 1 further including the step of removing said first underfill from said tips of said conductive contacts subsequent to said step of applying step said layer of first underfill to said surface of said device having said contacts extending therefrom.

6. The method of claim 5 wherein said removing step comprises the step of polishing at least the tips of said contacts.

7. The method of claim 5 wherein said removing step comprises the step of etching said layer of first underfill to expose said tips of said contacts.

8. The method of claim 5 wherein said removing step comprises the step of chemically mechanically polishing said layer of said first underfill to expose said tips of said contacts.

9. The method of claim 5 wherein said removing step comprises the step of reactively ion etching said layer of said first underfill to expose said tips of said contacts.

10. The method of claim 5 wherein said removing step comprises the step of laser milling said layer of first underfill to expose said tips of said contacts.

11. The method of claim 5 wherein said removing step comprises the step of laser ablating said layer of first underfill to expose said tips of said contacts.

12. The method of claim 1 wherein said step of applying said first underfill comprises the step of applying said layer of first underfill by at least one technique selected from the group of spinning, brushing, dispensing, spraying and screen printing.

13. The method of claim 1 wherein said step of partially curing said layer of first underfill comprises the step of partially curing said layer of first underfill utilizing a technique selected from the group of B-staging, soft baking, application of compressed gas, hot gas drying, oven heating, UV light curing and IR baking.

14. The method of claim 1 wherein said step of applying said layer of said second underfill to at least said pads on said substrate surface comprises the step of coating at least said pads with a fluxing agent.

15. The method of claim 1 wherein said step of applying said layer of said second underfill to at least said pads on said substrate surface comprises the step of coating at least said pads with a curing agent.

16. The method of claim 1 wherein said step of applying said layer of said second underfill to at least said pads on said substrate surface comprises the step of coating at least said pads with a curing agent.

17. The method of claim 1 wherein said step of applying said layer of said second underfill to at least said pads on said substrate surface comprises the step of coating at least said pads on said substrate surface with a polymer flux.

18. The method of claim 1 wherein said step of applying said layer of said second underfill to at least said pads on said substrate surface comprises the step of coating at least said pads on said substrate surface with an underfill with a filler load ranging from 0 to 30% by weight.

19. The method of claim 18 wherein said step of applying said layer of said second underfill to at least said pads on said substrate surface comprises the step of coating at least said pads on said substrate surface with an underfill with a filler load ranging from 0 to 10% by weight.

20. The method of claim 1 further including the step of curing said first underfill and said second underfill.

21. The method of claim 1 wherein said step of subjecting said device and said substrate to a reflow process to conductively couple said conductive contacts to said conductive pads comprises the step of applying forced hot gas to reflow said conductive contacts.

22. The method of claim 1 wherein said step of subjecting said device and said substrate to a reflow process to conductively couple said conductive contacts to said conductive pads comprises the step of applying forced hot air to said device and said substrate to reflow said conductive contacts.

23. The method of claim 1 wherein said step of subjecting said device and said substrate to a reflow process to conductively couple said conductive contacts to said conductive pads comprises the step of reflowing said conductive contacts within an infra red oven.

24. The method of claim 1 wherein said step of subjecting said device and said substrate to a reflow process to conductively couple said conductive contacts to said conductive pads comprises the step of reflowing said conductive contacts in a hot bar reflow process.

25. The method of claim 1 wherein said step of subjecting said device and said substrate to a reflow process to conductively couple said conductive contacts to said conductive pads comprises the step of reflowing said conductive contacts in a hot plate reflow process.

26. The method of claim 1 wherein said step of subjecting said device and said substrate to a reflow process to conductively couple said conductive contacts to said conductive pads comprises the step of reflowing said conductive contacts in a vapor phase reflow process.

27. The method of claim 1 wherein said step of subjecting said device and said substrate to a reflow process to conductively couple said conductive contacts to said conductive pads comprises the step of reflowing said conductive contacts in a fume gas reflow process.

28. The method of claim 1 wherein said layer of said second underfill comprises an unfilled underfill.

29. The method of claim 1 wherein said layer of said second underfill comprises a lightly filled underfill having a filler less than 30% by weight.

30. The method of claim 1 wherein said layer of said second underfill comprises a lightly filled underfill having a filler less than 10% by weight.
